(19) United States
(12) Patent Application Publication
(10) Pub. No.: US 2021/0253871 A1
(43) Pub. Date: Aug. 19, 2021

(54) CORROSION-RESISTANT CONDUCTIVE STRUCTURE AND CORROSION-RESISTANT COATING COMPOSITION

(71) Applicant: TPK Universal Solutions Limited, Wanchai (HK)

(72) Inventors: Lung-Pin Chen, Chiayi City (TW); Yi-Lung Yang, Taoyuan City (TW); Chun-Hung Chu, Hsinchu City (TW)

(21) Appl. No.: 16/934,198

(22) Filed: Jul. 21, 2020

(30) Foreign Application Priority Data
Feb. 14, 2020 (CN) 202010095678.8

(51) Int. Cl. C09D 5/08; C09D 7/63; H01B 5/14; H01B 1/02; B32B 15/09; B32B 27/36; B32B 15/02

(52) U.S. Cl. CPC C09D 5/086; C09D 7/63; H01B 5/14; C08K 5/3445; B32B 15/09; B32B 27/36; B32B 15/02; H01B 1/02

(57) ABSTRACT

A corrosion-resistant conductive structure includes: a substrate, a conductive layer, and a protective layer. The conductive layer is disposed on the substrate and includes a metal, a metal alloy, or a metal oxide. The protective layer overlies the conductive layer and includes a resin and a first component; the first component includes a heterocyclic dizane compound or a derivative thereof. A corrosion-resistant coating composition includes: a resin, a first component, and a solvent. The first component includes a heterocyclic dizane compound or a derivative thereof, wherein the concentration of the first component ranges from 0.01 mg/L to 180 mg/L.

### CROSS-REFERENCE TO RELATED APPLICATION

This application claims priority to China Application Serial Number 202010095678.8, filed Feb. 14, 2020, which is herein incorporated by reference in its entirety.

### BACKGROUND

### Field of Disclosure

The present disclosure relates to anti-corrosion treatment of metals, particularly, anti-corrosion treatment of metals for conductive function.

### Description of Related Art

In electronic devices, a protective layer is usually disposed on a conductive layer to prevent corrosion of materials in the conductive layer. For instance, the surface of copper can be covered with a layer of resin material to isolate the copper from factors (e.g., water or oxygen) causing metal corrosion in the environment, thereby achieving the effect of anti-corrosion. However, even if a protective layer of a resin material is disposed on the conductive layer, the material in the conductive layer often corrodes, resulting in a decrease in conductivity.

### SUMMARY

One aspect of the present disclosure provides a corrosion-resistant conductive structure including a substrate, a conductive layer, and a protective layer. The conductive layer is disposed on the substrate and includes metal, metal alloy, or metal oxide. The protective layer overlies the conductive layer and includes a resin and a first component; the first component includes a heterocyclic dizane compound or a derivative thereof.

Another aspect of the present disclosure provides a corrosion-resistant coating composition including a resin, a first component, and a solvent. The first component includes a heterocyclic dizane compound or a derivative thereof, wherein the concentration of the first component ranges from 0.01 mg/L to 180 mg/L.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are cross-sectional views of a corrosion-resistant conductive structure according to some embodiments of the present disclosure.

FIG. 2 is a schematic diagram of an environmental test for a conductive structure according to an experimental example of the present disclosure.

FIGS. 3A to 3C are scanning electron microscope images of the environmental test for some experimental examples of the present disclosure.

FIGS. 4A to 4C are scanning electron microscope images of the environmental test for a conductive structure according to some experimental examples of the present disclosure.

FIG. 5A is a schematic diagram of an environmental test for a conductive structure according to an experimental example of the present disclosure.

FIG. 5B is a diagram showing the result of the environmental test for the conductive structures according to some experimental examples of the present disclosure.

### DETAILED DESCRIPTION

The following disclosure provides many different embodiments, or examples, for implementing different features of the provided subject matter. Specific examples of components and arrangements are described below to simplify the present disclosure. Of course, these are only examples and are not intended to limit the present disclosure. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

One aspect of the present disclosure provides a corrosion-resistant coating composition including a resin, a first component, and a solvent. The details of each of the components in the corrosion-resistant coating composition are described below.

In some embodiments of the present disclosure, the resin is an ultraviolet-curable (UV-curable) resin or a heat-curable resin. In some examples, the resin comprises polyacrylate, epoxy, novalac, polyurethane (PU), polyimide (PI), polyether, polyester, polyvinyl butyral (PVB), or a combination thereof. In some embodiments, the resin may be an optically transparent resin.

In some embodiments, the concentration of the resin in the corrosion-resistant coating composition ranges from 0.1 to 10 weight percent, for example, 0.1, 0.5, 1, 2, 4, 6, 8, or 10 weight percent.

In some embodiments of the present disclosure, the first component includes a heterocyclic dizane compound or a derivative thereof having the structure of Chemical formula 1:

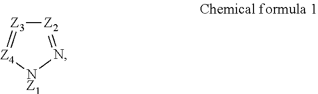

wherein Z₁ is hydrogen (H) or carbon (C), and Z₂, Z₃, and Z₄ are carbon (C).

In some embodiments, the heterocyclic dizane compound is, for example, Benzotriazole, the structural formula is

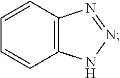

1,2,4-Triazole, the structural formula is

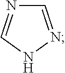

Pyrazole, the structural formula is

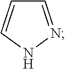

3,4-Dimethyl-1H-pyrazole, the structural formula is

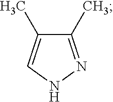

3,4,5-Trimethyl-1H-pyrazole, the structural formula is

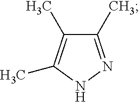

4-Ethyl-1H-pyrazole, the structural formula is

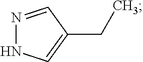

4-Fluoro-1H-pyrazole, the structural formula is

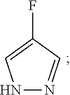

1H-Pyrazole, 3-methyl-5-(trifluoromethyl), the structural formula is

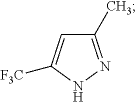

3-Methyl-4-phenylpyrazole, the structural formula is

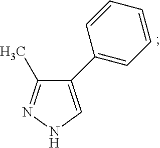

3-(4-methoxyphenyl)-1H-pyrazole, the structural formula is

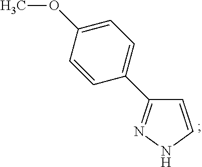

5-Methyl-1H-pyrazole, the structural formula is

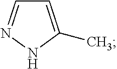

3-(4-Aminophenyl)pyrazole, also referred to as 4-(1H-pyrazol-3-yl)aniline, the structural formula is

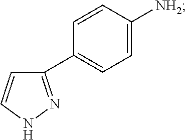 [SMILES: Nc1ccc(-c2cc[nH]n2)cc1]

2-(2-Aminophenyl)pyrazole, also referred to as 2-(1H-pyrazol-1-yl)aniline, the structural formula is

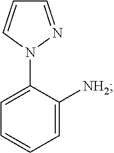 [SMILES: Nc1ccccc1-n1cccn1]

3-(2,5-Dimethoxyphenyl)-1H-pyrazole, the structural formula is

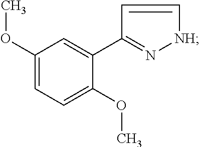

5-(2-Thienyl)pyrazole, the structural formula is

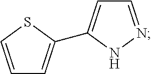

Methyl 5-hydroxy-1-methyl-1H-pyrazole-3-carboxylate, the structural formula is

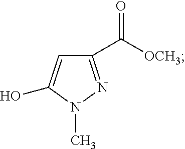

4-[5-(4-Methoxyphenyl)-1-(2-naphthyl)-4,5-dihydro-1H-pyrazole-3-yl]-7H-benzimidazo[2,1-a]benzo[de]isoquinolin-7-one, also referred to as Pyrazole-72, the structural formula is

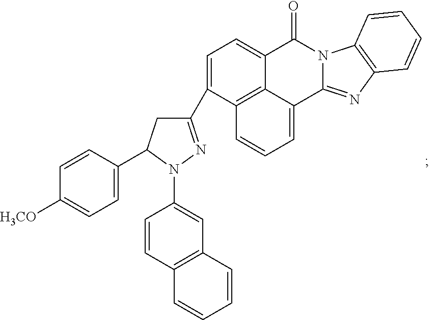 [SMILES: COc1ccc(C2CC(c3ccc4c(=O)n5c6ccccc6nc5c5cccc3c45)=NN2c2ccc3ccccc3c2)cc1]

Ethyl 5-amino-1-methyl-1H-pyrazole-4-carboxylate, the structural formula is

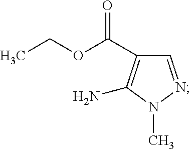

5-Methyl-1H-benzotriazole, the structural formula is

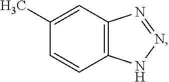

4-Phenyl-1H-1,2,3-triazole, the structural formula is

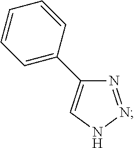 [SMILES: c1ccc(-c2c[nH]nn2)cc1]

4-Amino-4H-1,2,4-triazole, the structural formula is

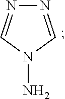

3-Methyl-1H-1,2,4-triazole, the structural formula is

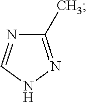

or 3-Amino-1,2,4-triazole, the structural formula is

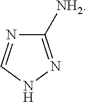

In some embodiments, in the corrosion-resistant coating composition, the concentration of the first component ranges from about 0.01 mg/L to 180 mg/L, for example, about 0.02, 0.05, 0.1, 0.2, 0.5, 0.7, 1, 5, 10, 20, 30, 40, 50, 60, 70, 80, 90, 100, 110, 120, 130, 140, 150, 160, 170, or 180 mg/L.

In some embodiments of the present disclosure, the solvent includes water, ethanol, isopropyl alcohol (IPA), acetone, tetrahydrofuran (THF), aprotic solvents (e.g., N-methylpyrrolidone (NMP), dimethylformamide (DMF), dimethylmethylene sulfoxide (DMSO)), propylene glycol methyl ether acetate (PGMEA), propylene glycol methyl ether (PGME), ethyl acetate (EAC), or a combination thereof.

In some embodiments, the concentration of the solvent in the corrosion-resistant coating composition ranges from 90 to 99.8 weight percent, for example, the solvent accounts for 92, 95, 97, or 99 weight percent.

In some embodiments of the present disclosure, the corrosion-resistant coating composition further comprises a second component including alkyamine, fluoroalkylamine, fluoroaniline, alkylthiol, fluoroalkylthiol, fluorothiophenol, a derivative thereof, or a combination thereof.

In some embodiments, the alkylamine included in the second component may be, for example, dodecylamine, the chemical formula is CH₃(CH₂)₁₀CH₂NH₂, and the structural formula is

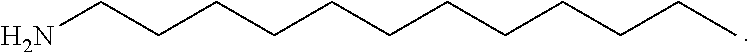

In other embodiments, the alkylamine included in the second component may also be, for example, Hexadecylamine, Nonylamine, 3-(Dimethylamino)-1-propylamine, 3-Phenyl-1-propylamine, 2-Phenylethyl)propylamine, or 3-(Dibutylamino)propylamine.

In some embodiments, the fluoroalkylamine included in the second component may be, for example, 1H,1H-Perfluorooctylamine, the structural formula is

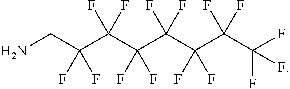 [SMILES: NCC(F)(F)C(F)(F)C(F)(F)C(F)(F)C(F)(F)C(F)(F)C(F)(F)F]

In other embodiments, the fluoroalkylamine included in the second component may also be, for example, 3-Fluoro-5-(trifluoromethyl)benzylamine, fluoro-4-isopropylphenyl)ethan-1-amine, [(5-Fluoro-1H-benzimidazol-2-yl)methyl]amine hydrochloride, or 4-[2-Fluoro-3-(trifluoromethyl)phenyl]-1,3-thiazol-2-amine.

In some embodiments, the fluoroaniline included in the second component may be, for example, 2,3,4,5,6-Pentafluoroaniline, and the structural formula is

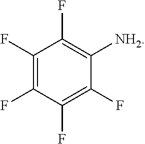 [SMILES: Nc1c(F)c(F)c(F)c(F)c1F]

In other embodiments, the fluoroaniline included in the second component may also be, for example, 3,4,5-Trifluoroaniline, 2,4,6-Trifluoroaniline, 3-Fluoro-4′-methyl[1,1′-biphenyl]-4-amine, or 2-Fluoroadenine.

In some embodiments, the alkylthiol included in the second component may be, for example, 1-Decanethiol, the chemical formula is CH₃(CH₂)₈CH₂SH, and the structural formula is

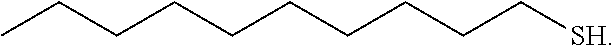

The second component may also include a derivative of alkylthiol, such as 2-Aminothiophenol, and the structural formula is

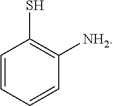

In other embodiments, the alkylthiol included in the second component may also be, for example, 1-Dodecanethiol, 1-Tetradecanethiol, 1-Octadecanethiol, or 1-Hexadecanethiol.

In some embodiments, the fluoroalkylthiol included in the second component may be, for example, 1H,1H,2H,2H-Perfluorodecanethiol, the chemical formula is CF₃(CF₂)₇CH₂CH₂SH, and the structural formula is

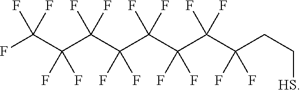 [SMILES: FC(F)(F)C(F)(F)C(F)(F)C(F)(F)C(F)(F)C(F)(F)C(F)(F)C(F)(F)CCS]

In other embodiments, the fluoroalkylthiol included in the second component may also be, for example, 2,2,2-Trifluoroethanethiol or 3,3,4,4,5,5,6,6,7,7,8,8,9,9,10,10,10-Heptadecafluoro-1-decanethiol.

In some embodiments, the fluorothiophenol included in the second component may be, for example, 2,3,4,5,6-pentafluorothiophenol, and the structural formula is

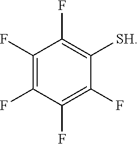 [SMILES: Fc1c(F)c(F)c(S)c(F)c1F]

In other embodiments, the fluorothiophenol included in the second component may also be, for example, 2-Fluorothiophenol, 3-Fluorobenzenethiol, 4-Fluorothiophenol, 3-Bromo-4-fluorothiophenol, 3,5-Difluorothiophenol, 3,4-Difluorothiophenol, 2,4-Difluorothiophenol, or 4-(Trifluoromethyl)thiophenol.

In some embodiments, the second component is fluoroalkylamine, fluoroalkylthiol, a derivative thereof, or a combination thereof. For example, the second component is 1H,1H,2H,2H-Perfluorodecanethiol.

In some embodiments, in the corrosion-resistant coating composition, the sum of the concentration of the first component plus the concentration of the second component ranges from 0.01 mg/L to 200 mg/L, for example, about 0.02, 0.05, 0.1, 0.2, 0.5, 0.7, 1, 5, 10, 20, 30, 40, 50, 60, 70, 80, 90, 100, 110, 120, 130, 140, 150, 160, 170, 180, 190, or 200 mg/L.

In some embodiments, in the corrosion-resistant coating composition, the ratio of the first component to the second component is 1:10-10:1. For example, the ratio of the first component to the second component is 1:8, 1:5, 1:1, 5:1, or 8:1.

The corrosion-resistant coating composition of some embodiments of the present disclosure has fluidity and can be coated on a surface of a conductive material (e.g., a metal nanowire) to suppress corrosion of the conductive material. In the corrosion-resistant coating composition, if the concentration of the first component or the sum of the concentration of the first component plus the concentration of the second component is less than the concentration range as mentioned above, a sufficient anti-corrosion effect cannot be achieved. If the concentration of the first component or the sum of the concentration of the first component plus the concentration of the second component is more than the concentration range as mentioned above, the hydrophobic property of the corrosion-resistant coating composition will be detrimental to the subsequent coating process.

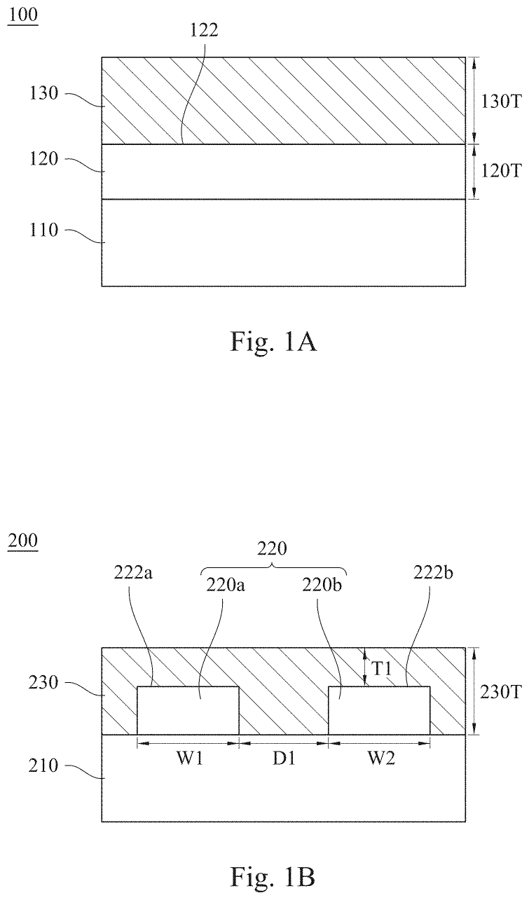

Another aspect of the present disclosure provides a corrosion-resistant conductive structure. FIGS. 1A and 1B illustrate cross-sectional views of a conductive structure according to some embodiments of the present disclosure.

FIG. 1A shows that a conductive structure 100 includes a substrate 110, a conductive layer 120, and a protective layer 130. The conductive layer 120 is disposed over the substrate 110, and the protective layer 130 is disposed over the conductive layer 120.

In some embodiments, the substrate 110 may be a flexible substrate or a rigid substrate. The flexible substrate may include, but is not limited to, polyethylene terephthalate (PET), cycloolefin polymer (COP), cyclic olefin copolymer (COC), polycarbonate (PC), poly(methyl methacrylate (PMMA), polyimide, polyethylene naphthalate (PEN), polyvinylidene difluoride (PVDF), polydimethylsiloxane (PDMS), or a combination thereof. The rigid substrate may include, but is not limited to, glass, wafer, quartz, silicon carbide, ceramics, or a combination thereof.

The conductive layer 120 is disposed on the substrate 110. In some embodiments, the conductive layer 120 includes a conductive material, such as metal, metal alloy, or metal oxide. In some embodiments, the material of the conductive layer 120 may be aluminum, palladium, gold, silver, nickel, copper, tin, iron, or an alloy thereof, such as brass. In some embodiments, the conductive layer 120 may include conductive material in the form of bulk, microwire, nanowire, mesh, particle, cluster, or sheet.

As used herein, a microwire refers to a structure having an aspect ratio (length:diameter) of at least 10 and a diameter of at least 1 micron and less than 1000 microns, a nanowire refers to a structure having an aspect ratio of at least 10 and a diameter of at least 1 nanometer and less than 1000 nanometers, a particle refers to a structure having an aspect ratio of less than 10 and a diameter of less than 1000 microns, and a cluster refers to a group of elements (particles, wires, etc.) integrally connected and having a total width of less than 1000 microns and a total length of less than 1000 microns. As used herein, a sheet refers to a layer of material having a width and a length that are substantially larger than a thickness of the layer (e.g., the width and length of a layer may each be 10 times or more the thickness of the layer). A mesh refers to a layer including a plurality of threads or wires that are interwoven, wherein a plurality of open spaces are generally defined between the plurality of threads or wires. Bulk refers to a layer formed by gathering or stacking many single atomic planes of at least one material or granular mixtures of at least one material.

In some examples, the conductive layer 120 is a transparent conductive layer, which includes a transparent matrix layer and a plurality of metal nanowires (e.g., silver nanowires) embedded in the transparent matrix layer. In some embodiments, the conductive layer 120 may be a single-layer structure or a multi-layer stack structure.

In some embodiments, the conductive layer 120 has a thickness 120T, which ranges from about 10 nm to 5 μm, preferably about from 20 nm to 1 μm, and more preferably from about 50 to 200 nm. For example, the thickness 120T may be 55, 60, 70, 100, 120, 150, 180, or 195 nm.

The protective layer 130 is disposed on the upper surface 122 of the conductive layer 120. In some embodiments, 75 to 95 weight percent of the protective layer 130 is the resin and 0.1 to 20 weight percent of the protective layer 130 is the first component. For example, 76, 80, 85, 90, 92, or 94 weight percent of the protective layer 130 is the resin and 0.2, 1.5, 1, 2, 5, 7, 9, 11, 13, 15, 17, or 19 weight percent of the protective layer 130 is the first component.

In other embodiments, 75 to 95 weight percent of the protective layer 130 is the resin, and 0.1 to 20 weight percent of the protective layer 130 is the sum of the first component plus the second component. For example, 76, 80, 85, 90, 92, 94 weight percent of the protective layer 130 is the resin, and 0.2, 1.5, 1, 2, 5, 7, 9, 11, 13, 15, 17, or 19 weight percent of the protective layer 130 is the sum of the first component plus the second component.

In some embodiments, the protective layer 130 is an optically transparent structure.

In some embodiments, the resin in the protective layer 130 includes polyacrylate, epoxy resin, phenolic resin, polyurethane, polyimide, polyether, polyester, polyvinyl butyral, or a combination thereof.

In some embodiments, the first component in the protective layer 130 includes a heterocyclic dizane compound or a derivative thereof. For example, the first component may be Benzotriazole, 1,2,4-Triazole, Pyrazole, 3,4-Dimethyl-1H-pyrazole, 3,4,5-Trimethyl-1H-pyrazole, 4-Ethyl-1H-pyrazole, 4-Fluoro-1H-pyrazole, 1H-Pyrazole, 3-methyl-5-(trifluoromethyl), 3-Methyl-4-phenylpyrazole, 3-(4-methoxyphenyl)-1H-pyrazole, 5-Methyl-1H-pyrazole, 3-(4-Aminophenyl)pyrazole (i.e., 4-(1H-pyrazol-3-yl)aniline), 2-(2-Aminophenyl)pyrazole (i.e., 2-(1H-pyrazol-1-yl)aniline), 3-(2,5-Dimethoxyphenyl)-1H-pyrazole, 5-(2-Thienyl)pyrazole, Methyl 5-hydroxy-1-methyl-1H-pyrazole-3-carboxylate, 4-[5-(4-Methoxyphenyl)-1-(2-naphthyl)-4,5-dihydro-1H-pyrazole-3-yl]-7H-benzimidazo[2,1-a]benzo[de]isoquinolin-7-one (i.e., Pyrazole-72), Ethyl 5-amino-1-methyl-1H-pyrazole-4-carboxylate, 5-Methyl-1H-benzotriazole, 4-Phenyl-1H-1,2,3-triazole, 4-Amino-4H-1,2,4-triazole, 3-Methyl-1H-1,2,4-triazole, or 3-Amino-1,2,4-triazole.

In some embodiments, the second component in the protective layer 130 includes alkylamine, fluoroalkylamine, fluoroaniline, alkylthiol, fluoroalkylthiol, fluorothiophenol, a derivative thereof, or a combination thereof.

In some embodiments, the alkylamine included in the second component in the protective layer 130 may be, for example, dodecylamine, and the chemical formula is CH₃(CH₂)₁₀CH₂NH₂.

In some embodiments, the fluoroalkylamine included in the second component in the protective layer 130 may be, for example, 1H,1H,2H,2H-Perfluorodecanethiol.

In some embodiments, the fluoroaniline included in the second component in the protective layer 130 may be, for example, 2,3,4,5,6-Pentafluoroaniline.

In some embodiments, the alkylthiol included in the second component in the protective layer 130 may be, for example, 1-decanethiol, and the chemical formula is CH₃(CH₂)₈CH₂SH. The second component in the protective layer 130 may also include a derivative of alkylthiol, for example, 2-aminothiophenol.

In some embodiments, the fluoroalkylthiol included in the second component in the protective layer 130 may be, for example, 1H,1H,2H,2H-Perfluorodecanethiol, and the chemical formula is CF₃(CF₂)₇CH₂CH₂SH.

In some embodiments, the fluorothiophenol included in the second component in the protective layer 130 may be, for example, 2,3,4,5,6-pentafluorothiophenol.

In some embodiments, the second component in the protective layer 130 is fluoroalkylamine, fluoroalkylthiol, a derivative thereof, or a combination thereof. For example, the second component is 1H,1H,2H,2H-Perfluorodecanethiol.

In some embodiments, the thickness 130T of the protective layer 130 ranges from 10 nm to 0.5 cm, for example, from 20 nm to 4000 μm, from 25 nm to 1000 μm, from 30 nm to 200 μm, from 50 nm to 10 μm, or from 60 nm to 1 μm.

FIG. 1B illustrates a cross-sectional view of a corrosion-resistant conductive structure 200. The conductive structure 200 is similar to the conductive structure 100, except for that in the conductive structure 200, the conductive layer 220 disposed on the substrate 110 is patterned conductive layers including conductive layers 220a and 220b; further, the protective layer 230 overlies and surrounds the conductive layers 220a and 220b. Therefore, an anti-corrosion barrier is provided on the surfaces 222a and 222b and side surfaces of the conductive layers 220a and 220b, and the anti-corrosion ability for the metal in the conductive layer 220 is strengthened.

In some embodiments, the gap D1 between the conductive layer 220a and the conductive layer 220b ranges from about 5 to 500 μm. For example, the gap D1 is about 6, 10, 15, 30, 50, 70, 100, 200, 250, 300, 400, 450, 480, or 490 μm. In some embodiments, the conductive layers 220a and 220b have widths W1 and W2 ranging from about 5 to 1000 μm, respectively. For example, the widths W1 and W2 are about 6, 10, 50, 100, 200, 500, 700, 900, 950, or 990 μm.

In some embodiments, the thickness 230T of the protective layer 230 ranges from 40 nm to 0.5 cm, for example, from 40 nm to 4000 μm, from 45 nm to 1000 μm, from 50 nm to 200 μm, from 60 nm to 50 μm, from 70 nm to 10 μm, or 80 nm to 1 μm. The thickness T1 of the protective layer 230 measured from the upper surface 222a of the conductive layer 220a and measured from the upper surface 222b of the conductive layer 220b is at least 10 nm.

In some embodiments of the present disclosure, the conductive layer 120 or the conductive layer 220 includes metal nanowires. Metal nanowires may be based on any suitable metal including, but not limited to, silver, gold, copper, nickel, or gold-plated silver.

In some embodiments, the conductive layer 120 or the conductive layer 220 includes silver nanowires. The silver nanowires can be connected to each other to form a silver nanowire conductive network. A suitable aspect ratio of the nanowires may be, for example, from 10 to 100,000. When nanowires with a relatively high aspect ratio are used, a conductive network can be implemented by using a lower density of nanowires, such that the conductive network is essentially transparent under the visible light ranging from about 440 nm to 700 nm. It is noted that after metal such as silver is nanomized, the ratio of the surface of the metal per unit volume will be greatly increased; i.e., a higher proportion of atoms are located on the surface of the material, such that the surface of the material has high chemical activity. In addition, at such a small size, the atoms or the surrounding electrons will have quantum efficiency, such that the characteristics of the surface of the material may be different from those of macro-scale materials. Compared with large-sized metal materials, it is much more difficult to suppress corrosion for micro-sized metals such as silver nanowires; the composition of the corrosion-resistant coating provided in the disclosure can provide adequate protection for both macro-sized and micro-sized metal conductive layers.

In some embodiments, the protective layer 130 and the protective layer 230 may be formed of the corrosion-resistant coating composition described above. In detail, the corrosion-resistant coating composition can be coated on the conductive layer 120 or the conductive layer 220 by any suitable method, and then the protective layer 130 is formed on the surface of the conductive layer 120 by curing or baking processes.

In some embodiments, the corrosion-resistant coating composition can be directly applied to the surface of the conductive material, and then a patterned conductive layer 120 and a patterned protective layer 130 are formed through an etching process. In other words, the protective layer 130 is formed only on the upper surface 122 of the conductive layer 120, as shown in FIG. 1A. In other embodiments, the patterned conductive layers 220a, 220b may be formed through an etching process, and then the corrosion-resistant coating composition is coated on the patterned conductive layers 220a, 220b, as shown in FIG. 1B.

In some embodiments, after the corrosion-resistant coating composition is coated on the conductive layer, the chemical components included in the first component and/or the second component may self assemble on the metal surface of the conductive layer to form a single layer, thereby protecting the metal surface from corrosion. In other embodiments, after the corrosion-resistant coating composition is coated on the conductive layer, the chemical components included in the first component and/or the second component may be sublimated into the gas phase; then the chemical components are deposited on the metal surface of the conductive layer to form a single layer through the mechanism of molecular layer deposition, thereby protecting the metal surface from corrosion. Therefore, the first component and/or the second component in the corrosion-resistant coating composition modify the metal surface of the conductive layer to form a hydrophobic surface and inhibit the metal ionization of the layer. In addition, the first component and/or the second component in the corrosion-resistant coating composition can form a passivation layer on the metal surface, thereby isolating from the water and protecting the metal from corrosion factors such as oxidation, sulfuration, or the like.

The following describes the embodiments of the present disclosure in more detail with reference to experimental examples, but the present disclosure is not limited to the following experimental examples.

### Experimental Example 1

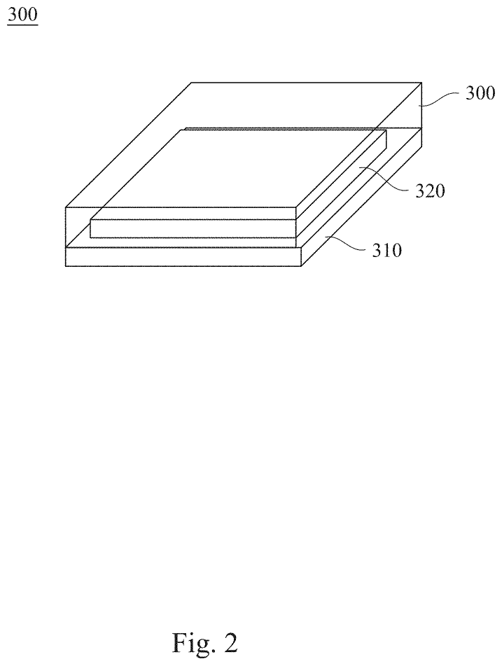

Referring to FIG. 2, the conductive layer structure 300 includes a substrate 310, a conductive layer 320, and a protective layer 330. In Experimental Example 1-1, the protective layer 330 includes a resin and a first component; in Experimental Example 1-2, the protective layer 330 includes a resin and a second component; in Experimental Example 1-3, the protective layer 330 includes a resin, a first component, and a second component. Then, an environmental test was performed; after the conductive structures of Experimental Examples 1-1, 1-2, and 1-3 were placed in an environment under 85° C. and relative humidity of 85% for 168 hours (7 days), the surface corrosion degree of the conductive layers 320 was observed.

In Experimental Examples 1-1, 1-2, and 1-3, the resin concentration in the coating liquid was 0.7 weight percent. The first component in the coating liquid of Experimental Example 1-1 was benzotriazole, and the concentration was 60 mg/L. The second component in the coating liquid of Experimental Example 1-2 was 2,3,4,5,6-pentafluorothiophenol, and the concentration was 60 mg/L. In Experimental Example 1-3, the first component in the coating liquid was benzotriazole, and the concentration was 30 mg/L; the second component was 2,3,4,5,6-pentafluorothiophenol, and the concentration was 30 mg/L.

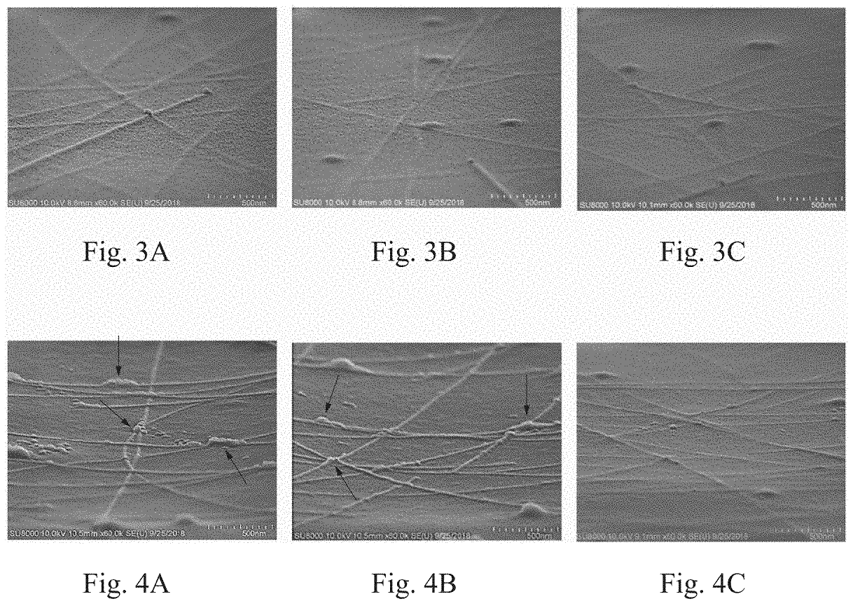

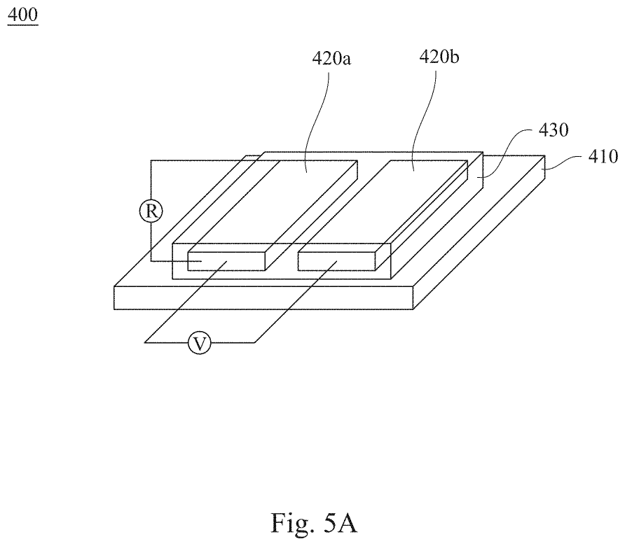

FIGS. 3A, 3B, and 3C are respectively scanning electron microscope images of the conductive structures of Experimental Examples 1-1, 1-2, and 1-3 before the environmental test (at the 0th hour). FIGS. 4A, 4B, and 4C are respectively scanning electron microscope images of the conductive structures of Experimental Examples 1-1, 1-2, and 1-3 after 168 hours of the environmental test.

FIG. 4A shows that in a conductive structure including a protective layer having the first component, the metal of the conductive layer had some corrosion after 168 hours of environmental test. FIG. 4B shows that in a conductive structure including a protective layer having the second component, the metal of the conductive layer had some corrosion after 168 hours of environmental test. FIG. 4C shows that in a conductive structure including a protective layer having the first component and the second component, no corrosion occurs in the metal of the conductive layer after 168 hours of environmental test. Therefore, in the conductive structure, a protective layer including both the first component and the second component provides a better anti-corrosion effect than a protective layer including only the first component or only the second component.

### Experimental Example 2

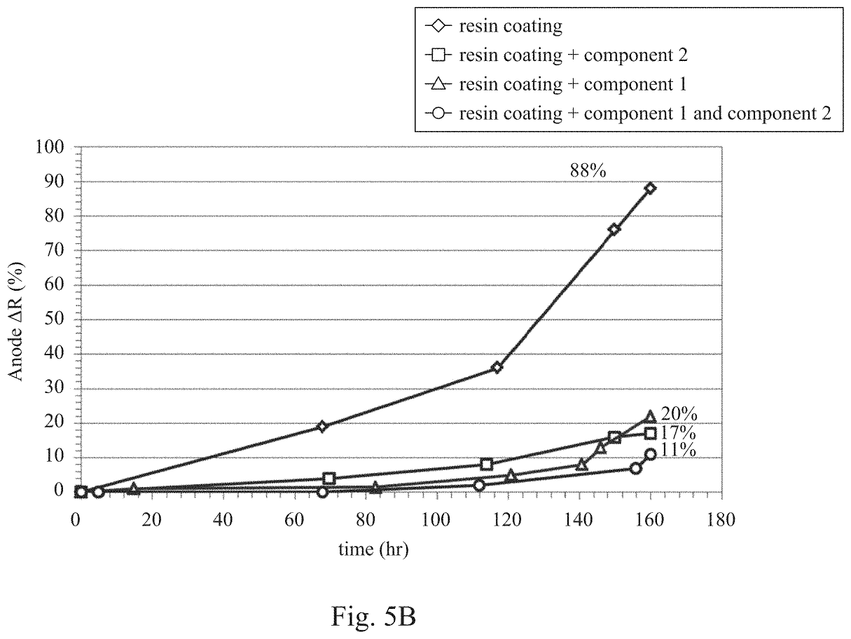

Referring to FIG. 5A, a conductive layer 400 includes a substrate 410, conductive layers 420a and 420b, and a protective layer 430. The substrate 410 is a polyethylene terephthalate (PET) substrate and has a thickness of 50 μm. The conductive layers 420a and 420b are conductive layers formed of silver nanowires, each of the conductive layers 420a and 420b has a thickness of about 30 nm and a width of about 200 μm, and a pitch between the conductive layers 420a and 420b is about 30 μm. Each of the conductive layers 420a and 420b has a sheet resistance of 70Ω/□. The thickness of the protective layer 430 is about 40 nm, that is, the thickness of the protective layer 430 measured from the upper surfaces of the conductive layers 420a and 420b is about 10 nm. 98 weight percentage of the protective layer 430 is polymethyl methacrylate resin (acrylic resin).

In Experimental Example 2-1, the protective layer 430 includes a resin and a first component; in Experimental Example 2-2, the protective layer 430 includes a resin and a second component; in Experimental Example 2-3, the protective layer 430 includes a resin, a first component and a second component. Moreover, a Comparative Example 1 is included in the test; the difference between the conductive structures of Comparative Example 1 and the conductive structures of the Experimental Examples 2-1, 2-2, and 2-3 is that the protective layer of Comparative Example 1 includes only polymethyl methacrylate resin but no first component and no second component.

In Experimental Examples 2-1, 2-2, 2-3, and Comparative Example 1, the resin concentration in the coating liquid was 0.7 weight percent. The first component in the coating liquid of Experimental Example 2-1 was benzotriazole, and the concentration was 60 mg/L. The second component in the coating liquid of Experimental Example 2-2 was 2,3,4,5,6-pentafluorothiophenol, and the concentration was 60 mg/L. In Experimental Example 2-3, the first component in the coating liquid was benzotriazole, and the concentration was 30 mg/L, and the second component was 2,3,4,5,6-pentafluorothiophenol, and the concentration was 30 mg/L.

The environmental test for the conductive structures of Experimental Examples 1 and Comparative Example 1 was performed at a temperature of 85° C., a relative humidity of 85%, and a DC voltage of 12 V; the results are shown in FIG. 5B. Referring to FIG. 5B, after 160 hours, the change in the anode resistance of Comparative Example 1 is 88%; the change in the anode resistance of Experimental Example 2-1 is 20%; the change in the anode resistance of Experimental Example 2-2 is 17%; the change in anode resistance of Experimental Example 2-3 was 11%.

As shown in FIG. 5B, in the conductive structure, the protective layers having the first component or the second component provided a significant anti-corrosion effect. In addition, a protective layer having both the first component and the second component provided a better anti-corrosion effect than a protective layer having only the first component or only the second component.

As described above, according to some embodiments of the present disclosure, a corrosion-resistant coating composition and a conductive structure including a corrosion-resistant protective layer are provided. The conductive structure can be applied to any electronic device, such as, but not limited to, transparent electrodes in a liquid crystal display, a touch panel, an electroluminescent device, or a thin film photovoltaic cell. Compared with the prior art, the protective layer provided by some embodiments of the present disclosure provides a strong anti-corrosion barrier, which can protect the conductive layer in the conductive structure, and solves the problem related to corrosion of conductive layers.

In addition, it will be appreciated that micro-size alters the characteristics of a material; some conventional hydrophobic treatment that can be used to inhibit metal corrosion for large-size bulk metal layers may not be sufficient to protect metal nanowires, resulting in a large increase in the resistance, short circuit, or yellowing and reduced transparency for metal nanowires. The experiments of the present disclosure confirmed that the protective layer provided in some embodiments of the present disclosure can effectively protect various conductive layers in the form of bulk, microwire, nanowire, mesh, particle, cluster, or sheet, and significantly lower the proportion of the increase in resistance of the conductive layers over time.

Further, because the protective layer provided in the embodiments of the present disclosure can be disposed on the conductive layer of a finished product, rather than just a structure in a transition process that is removed after a hydrophobic treatment, the protective layer can provide longer-lasting protection. Moreover, because the protective layer provided in the embodiments of the present disclosure can be used as a part of a finished structure, the material, the composition, and the ratio of the components of the protective layer can be disposed in accordance with requirements such as electrical properties, optical properties, refractive index, material adhesion, or flexibility, in order to overcome the problems related to electrical properties, optical properties, refractive index, material adhesion, or flexibility in conventional conductive structures; accordingly, a more reliable conductive structure can be implemented.

The foregoing has outlined features of several embodiments so that those skilled in the art can better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A corrosion-resistant conductive structure comprising:
a substrate;
a conductive layer disposed on the substrate, wherein the conductive layer comprises metal, metal alloy, or metal oxide; and
a protective layer overlying the conductive layer, wherein the protective layer comprises:
a resin; and
a first component comprising a heterocyclic dizane compound or a derivative thereof.

2. The corrosion-resistant conductive structure of claim 1, wherein the conductive layer comprises a conductive material in a form of bulk, microwire, nanowire, mesh, particle, cluster, or sheet.

3. The corrosion-resistant conductive structure of claim 1, wherein the conductive layer comprises a plurality of silver nanowires.

4. The corrosion-resistant conductive structure of claim 1, wherein the conductive layer is a transparent conductive layer.

5. The corrosion-resistant conductive structure of claim 1, wherein a weight percentage of the resin in the protective layer ranges from 75% to 95%.

6. The corrosion-resistant conductive structure of claim 1, wherein a weight percentage of the first component in the protective layer ranges from 0.1% to 20%.

7. The corrosion-resistant conductive structure of claim 1, wherein the heterocyclic dizane compound or the derivative thereof has a structure of Chemical formula 1, 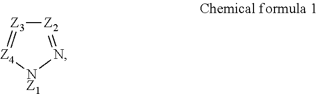
wherein Z₁ is hydrogen (H) or carbon (C), and Z₂, Z₃, and Z₄ are carbon (C).

8. The corrosion-resistant conductive structure of claim 1, wherein the heterocyclic dizane compound is Benzotriazole, 1,2,4-Triazole, Pyrazole, 3,4-Dimethyl-1H-pyrazole, 3,4,5-Trimethyl-1H-pyrazole, 4-Ethyl-1H-pyrazole, 4-Fluoro-1H-pyrazole, 1H-Pyrazole, 3-methyl-5-(trifluoromethyl), 3-Methyl-4-phenylpyrazole, 3-(4-methoxyphenyl)-1H-pyrazole, 5-Methyl-1H-pyrazole, 3-(4-Aminophenyl)pyrazole, 2-(2-Aminophenyl)pyrazole, 3-(2,5-Dimethoxyphenyl)-1H-pyrazole, 5-(2-Thienyl)pyrazole, Methyl 5-hydroxy-1-methyl-1H-pyrazole-3-carboxylate, 4[5-(4-Methoxyphenyl)-1-(2-naphthyl)-4,5-dihydro-1H-pyrazole-3-yl]-7H-benzimidazo[2,1-a]benzo[de]isoquinolin-7-one, Ethyl 5-amino-1-methyl-1H-pyrazole-4-carboxylate, 5-Methyl-1H-benzotriazole, 4-Phenyl-1H-1,2,3-triazole, 4-Amino-4H-1,2,4-triazole, 3-Methyl-1H-1,2,4-triazole, or 3-Amino-1,2,4-triazole.

9. The corrosion-resistant conductive structure of claim 1, wherein the protective layer further comprises a second component, wherein the second component comprises alkylamine, fluoroalkylamine, fluoroaniline, alkylthiol, fluoroalkylthiol, fluorothiophenol, a derivative thereof, or a combination thereof.

10. The corrosion-resistant conductive structure of claim 9, wherein the second component comprises fluoroalkylamine, fluoroalkylthiol, a derivative thereof, or a combination thereof.

11. The corrosion-resistant conductive structure of claim 9, wherein a sum of a weight percentage of the first component plus a weight percentage of the second component ranges from 0.1% to 20%.

12. The corrosion-resistant conductive structure of claim 9, wherein a ratio of the first component to the second component is 1:10-10:1.

13. The corrosion-resistant conductive structure of claim 1, wherein the protective layer has a thickness ranging from about 40 nm to about 0.5 cm.

14. A corrosion-resistant coating composition comprising:
a resin;
a first component comprising a heterocyclic dizane compound or a derivative thereof, wherein a concentration of the first component ranges from 0.01 mg/L to 180 mg/L; and
a solvent.

15. The corrosion-resistant coating composition of claim 14, wherein the heterocyclic dizane compound or the derivative thereof has a structure of Chemical formula 1, 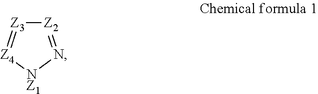
wherein Z₁ is hydrogen (H) or carbon (C), and Z₂, Z₃, and Z₄ are carbon 3 (C).

16. The corrosion-resistant coating composition of claim 14, wherein the heterocyclic dizane compound is Benzotriazole, 1,2,4-Triazole, Pyrazole, 3,4-Dimethyl-1H-pyrazole, 3,4,5-Trimethyl-1H-pyrazole, 4-Ethyl-1H-pyrazole, 4-Fluoro-1H-pyrazole, 1H-Pyrazole, 3-methyl-5-(trifluoromethyl), 3-Methyl-4-phenylpyrazole, 3-(4-methoxyphenyl)-1H-pyrazole, 5-Methyl-1H-pyrazole, 3-(4-Aminophenyl)pyrazole, 2-(2-Aminophenyl)pyrazole, 3-(2,5-Dimethoxyphenyl)-1H-pyrazole, 5-(2-Thienyl)pyrazole, Methyl 5-hydroxy-1-methyl-1H-pyrazole-3-carboxylate, 4[5-(4-Methoxyphenyl)-1-(2-naphthyl)-4,5-dihydro-1H-pyrazole-3-yl]-7H-benzimidazo[2,1-a]benzo[de]isoquinolin-7-one, Ethyl 5-amino-1-methyl-1H-pyrazole-4-carboxylate, 5-Methyl-1H-benzotriazole, 4-Phenyl-1H-1,2,3-triazole, 4-Amino-4H-1,2,4-triazole, 3-Methyl-1H-1,2,4-triazole, or 3-Amino-1,2,4-triazole.

17. The corrosion-resistant coating composition of claim 14, further comprising a second component, wherein the second component comprises alkylamine, fluoroalkylamine, fluoroaniline, alkylthiol, fluoroalkylthiol, fluorothiophenol, a derivative thereof, or a combination thereof.

18. The corrosion-resistant coating composition of claim 17, wherein the second component comprises fluoroalkylamine, fluoroalkylthiol, a derivative thereof, or a combination thereof.

19. The corrosion-resistant coating composition of claim 17, wherein a sum of the concentration of the first component plus a concentration of the second component is 0.01 mg/L to 200 mg/L.

20. The corrosion-resistant coating composition of claim 17, wherein a ratio of the first component to the second component is 1:10-10:1.
